(19) United States
(12) Patent Application Publication
(10) Pub. No.: US 2022/0214398 A1
(43) Pub. Date: Jul. 7, 2022

(54) EVALUATION METHOD FOR HOT CARRIER EFFECT DEGRADED PERFORMANCE

(71) Applicant: CHANGXIN MEMORY TECHNOLOGIES, INC., Hefei City (CN)

(72) Inventors: Jian HU, Hefei City (CN); Kang LV, Hefei City (CN); Yang XIONG, Hefei City (CN)

(21) Appl. No.: 17/455,992

(22) Filed: Nov. 22, 2021

Related U.S. Application Data
(63) Continuation of application No. PCT/CN2021/108412, filed on Jul. 26, 2021.

(30) Foreign Application Priority Data
Jan. 4, 2021 (CN) 202110004222.0

(51) Int. Cl. G01R 31/3183; G01R 31/26

(52) U.S. Cl. CPC G01R 31/3183; G01R 31/2621; G01R 31/2642

(57) ABSTRACT

Embodiments of the present application provide an evaluation method for hot carrier effect degraded performance, which includes: providing at least one wordline and at least one wordline driver; performing an electrical test on the wordline; performing a characteristic test on a sample passing the electrical test, to obtain a first performance parameter; inputting an AC signal to an input end of the wordline driver, to control the wordline to be repeatedly on and off through the wordline driver; performing the electrical test on the wordline; and performing the characteristic test on the sample passing the electrical test, to obtain a second performance parameter, and evaluating the hot carrier effect degraded performance of the wordline driver according to the first performance parameter and the second performance parameter.

### CROSS-REFERENCE TO RELATED APPLICATIONS

This application is a continuation application of International Patent Application No. PCT/CN2021/108412, filed on Jul. 26, 2021, which claims priority to Chinese Patent Application No. 202110004222.0, filed with the Chinese Patent Office on Jan. 4, 2021 and entitled “EVALUATION METHOD FOR HOT CARRIER EFFECT DEGRADED PERFORMANCE.” International Patent Application No. PCT/CN2021/108412 and Chinese Patent Application No. 202110004222.0 are incorporated herein by reference in their entireties.

### TECHNICAL FIELD

Embodiments of the present application relate to the field of semiconductors, and in particular to an evaluation method for hot carrier effect degraded performance.

### BACKGROUND

The wide application of electronic devices has imposed increased requirements on their performance, e.g., the stability of the performance of a semiconductor device in the electronic device. For a long-term reliable operation of the semiconductor device, the semiconductor device typically undergoes a reliability test for product performance before its shipment, and this aims at ensuring that the change in the performance of the semiconductor device within a preset period of time is within a preset threshold. The Hot Carrier Injection (HCI) effect is a critical factor affecting the performance of the semiconductor device, and will directly result in degradation of the performance of the semiconductor device. The hot carrier test for semiconductor devices is performed in accordance with the standards of Joint Electron Device Engineering Council (JEDEC), and involves inputting a voltage signal to a semiconductor device to measure the electrical performance of this semiconductor device and calculating the amount of electrical performance degradation of the semiconductor device.

In the prior art, the amount of degradation of the performance parameters of the semiconductor device is acquired by applying a constant overvoltage signal, and therefore the lifetime of the semiconductor device under overvoltage conditions is determined according to the amount of degradation of the performance parameters and overvoltage time. Further, the lifetime under normal operating conditions is deduced, using a mathematical linear model, from the lifetime under overvoltage conditions. In the prior art, however, the hot carrier test is carried out under a DC signal, whereas the semiconductor device in fact operates under an AC voltage signal. Thus, the result of the lifetime of the semiconductor device that is calculated on the basis of the equivalent conversion of the DC and AC signals is inaccurate, while at the same time failing to reflect the influence of the actual performance parameters of the semiconductor device upon the performance. At present, an accurate test method for the hot carrier effect degraded performance of the semiconductor device is absent.

### SUMMARY

The embodiments of the present application provide an evaluation method for hot carrier effect degraded performance, which includes: providing at least one wordline and at least one wordline driver; performing an electrical test on the wordline; performing a characteristic test on a sample passing the electrical test, to obtain a first performance parameter; inputting an AC signal to an input end of the wordline driver, to control the wordline to be repeatedly on and off through the wordline driver; performing the electrical test on the wordline; and performing the characteristic test on the sample passing the electrical test, to obtain a second performance parameter, and evaluating the hot carrier effect degraded performance of the wordline driver according to the first performance parameter and the second performance parameter.

### BRIEF DESCRIPTION OF DRAWINGS

The exemplary descriptions of one or more embodiments are made by using the corresponding drawings. The figures of the drawings are not shown to scale unless specifically stated.

FIG. 1 is a flow chart of the evaluation method for hot carrier effect degraded performance according to the embodiments of the present application;

FIG. 2 is a test circuit according to the embodiments of the present application;

FIG. 3 is a schematic diagram of the voltage changes at the input and output ends of the wordline driver according to the embodiments of the present application;

FIG. 4 is a schematic diagram of the wordline position according to the embodiments of the present application; and

FIG. 5 is a schematic diagram of the change in characteristic test results according to the embodiments of the present application.

### DESCRIPTION OF EMBODIMENTS

In order to make the objectives, the technical solutions, and the advantages of the embodiments of the present application clearer, the detailed description of the embodiments of the present application is given below in combination with the accompanying drawings. However, the ordinary skills in the art can understand that many technical details are provided in the embodiments of the present application so as to make the readers better understand the present application. However, even if these technical details are not provided and based on a variety of variations and modifications of the following embodiments, the technical solutions sought for protection in the present application can also be realized.

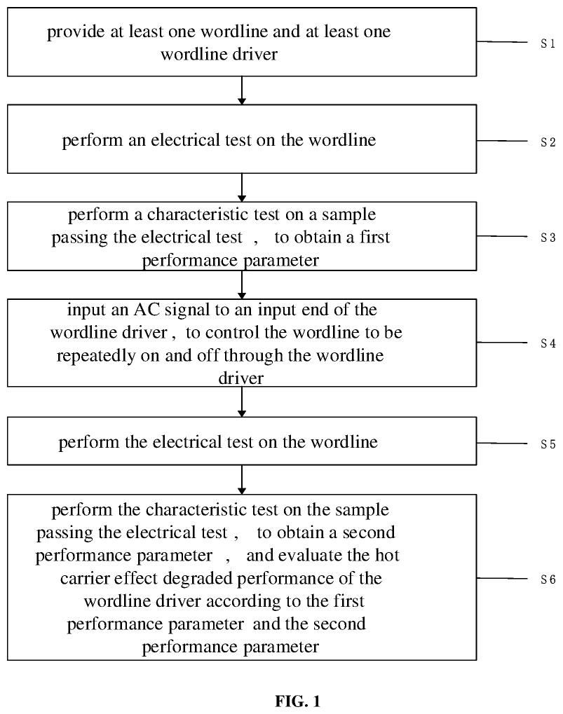

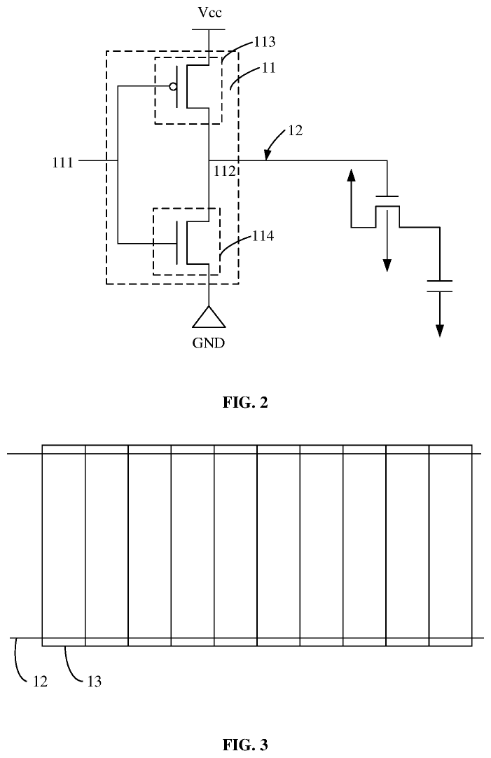

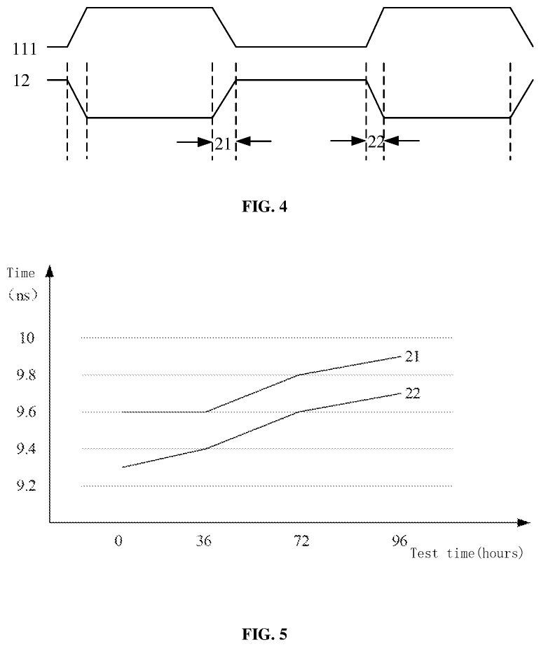

FIG. 1 is a flow chart of the evaluation method for hot carrier effect degraded performance according to the embodiments of the present application; FIG. 2 is a test circuit according to the embodiments of the present application; FIG. 3 is a schematic diagram of the voltage changes at the input and output ends of the wordline driver according to the embodiments of the present application; FIG. 4 is a schematic diagram of the wordline position according to the embodiments of the present application; and FIG. 5 is a schematic diagram of the change in characteristic test results according to the embodiments of the present application.

In this embodiment, the evaluation method for hot carrier effect degraded performance includes the following steps, as shown in FIG. 1: S1: providing at least one wordline and at least one wordline driver.

In this embodiment, in particular as shown in FIG. 2, a wordline 12 and a wordline driver 11 are provided. The wordline 12 and the wordline driver 11 constitute a test circuit. An input end 111 of the wordline driver 11 is configured to receive an input voltage signal, an output end 112 of the wordline driver 11 is configured for connection with the wordline 12, and the voltage of the output end 112 of the wordline driver 11 and the voltage of the wordline 12 can be controlled by adjusting the voltage signal of the input end 111 of the wordline driver 11. In other words, whether the performance parameters of the wordline driver 11 are acceptable or whether the basic functions are valid can be evaluated according to the change of the voltage of the wordline 12 under an AC signal, along with the AC signal, i.e., timing change in memory timing.

In some embodiments, the wordline driver 11 includes a PMOS transistor 113 and an NMOS transistor 114. A gate of the PMOS transistor 113 and a gate of the NMOS transistor 114 are connected to function as the input end 111 of the wordline driver 11. A drain of the PMOS transistor 113 and a drain of the NMOS transistor 114 are connected to function as the output end 112 of the wordline driver 11. A source of the PMOS transistor 113 is connected with a working power supply Vcc, and a source of the NMOS transistor 114 is connected with a ground terminal GND. The working power supply Vcc maybe 3.3 V.

In this embodiment, the wordline 12 and the wordline driver 11 are located within an array region of a wafer. As compared to evaluating the hot carrier effect degraded performance of the wordline and the wordline driver inside a scribe line of the wafer, evaluating the hot carrier effect degraded performance of the wordline 12 and the wordline driver 11 in the array region can lead to a more accurate evaluation for the influence of the hot carrier effect upon the performance of one physical storage or one wordline in the array region of the wafer.

In this embodiment, with combined reference to FIG. 2 and FIG. 3, the wordline 12 is located at the edge of a physical storage 13. During the manufacturing process of the wordline 12, the wordline at the edge of the physical storage has a relatively poor dimensional uniformity due to the optical proximity effect, and meanwhile the performance parameters of the wordline 12 at the edge of the physical storage 13 are more susceptible to the external environment. As compared to the wordline located in a middle region, the wordline 12 located at the edge has higher volatility and lower stability in terms of its own performance parameters, namely it is more difficult to meet the preset requirements for performance parameters or even damage is likely to occur, the impact on the evaluation result is tremendous, and the evaluation result based on the wordline 12 at the edge is highly likely to characterize the unacceptability of the performance parameters or the failure of the basic functions in the wordline driver 11. Therefore, by evaluating the wordline driver 11 through the wordline 12 at the edge, the wordline driver 11 can be considered as acceptable or valid when the acceptability or validness of the wordline driver 11 is characterized by the evaluation result.

In some embodiments, in a direction of arrangement of the wordlines within the same physical storage 13, the wordline 12 includes at least one of a second wordline or a penultimate wordline. With respect to a first wordline and a last wordline, the second wordline and the penultimate wordline are not only located at the edge of the physical storage 13, but are also affected by two adjacent wordlines and thus have higher volatility and worse stability in terms of their performance parameters. Hence, by evaluating the wordline driver 11 through at least one of the second wordline or the penultimate wordline, the evaluation result will be given a better applicability.

In this embodiment, the wordline driver 11 is a functional circuit configured for practical read and write operations, rather than a model circuit dedicated for testing. The model circuit is usually an equivalent circuit or a circuit of the same type for the functional circuit. The equivalent circuit refers to a circuit in which the circuit elements and the connection relationships are different and yet the same output signal can be attained by controlling an input signal at an input end. The circuit of the same type refers to a circuit in which the circuit elements and the connection relationships are identical and yet there are different performance parameters in the elements. The test result obtained from a test that utilizes the model circuit typically needs to be converted by a conversion factor, but the determination for this conversion factor may be inaccurate. In other words, performing a test directly through the functional circuit is favorable for accurate acquisition of the evaluation result.

S2: performing an electrical test on the wordline.

In this embodiment, the electrical test needs to be performed on the wordline 12 before a characteristic test is performed on the wordline 12, in order to ensure that the subsequent characteristic test can be effectively performed. An object on which the electrical test is performed may be not only one or more wordlines, but also the entire storage. In some embodiments, the test sample for the electrical test may be memory chips that may have a specification of 8 GB×8.

All the test samples on which the characteristic test is to be performed need to undergo the electrical test, in order to ensure that the test samples have the corresponding electrical performance and that there are no defects that may affect the evaluation result. In general, the electrical test only verifies whether the test samples have the corresponding electrical performance, and picks out those samples with unacceptable electrical performance, with no regard for the functional parameters of the test samples. This helps to avoid the situation where the issues of the test sample itself cause interference to the evaluation result and guarantee the validness of the evaluation result accordingly.

S3: performing a characteristic test on a sample passing the electrical test, to obtain a first performance parameter.

In this embodiment, the characteristic test includes applying an AC signal to the wordline driver 11, to control, through a high voltage, the PMOS transistor 113 to be turned off and the NMOS transistor 114 to be turned on, which corresponds to the turn-off of the wordline 12, and also to control, through a low voltage, the PMOS transistor 113 to be turned on and the NMOS transistor 114 to be turned off, which corresponds to turn-on of the wordline 12. The performance parameters of the wordline 12 include addressing delay time and pre-charging time in memory timing, and the first performance parameter includes first addressing delay time and first pre-charging time.

Referring to FIG. 4, when the AC signal is input to the input end 111 of the wordline driver 11, the voltage of the output end 112 and the voltage of the wordline 12 change accordingly. Based on the voltage change of the wordline 12, the addressing delay time 21 and the pre-charging time 22 in the memory timing of the wordline 12 can be acquired. In some embodiments, the PMOS transistor 113 is controlled to be turned on and the NMOS transistor 114 is controlled to be turned off, so as to acquire the addressing delay time 21; and the PMOS transistor 113 is controlled to be turned off and the NMOS transistor 114 is controlled to be turned on, so as to acquire the pre-charging time 22.

In this embodiment, subsequent to acquisition of the first performance parameters of all the test samples, those test samples that do not meet the preset performance requirement are filtered out, which ensures that the test samples for the subsequent tests have superior performance parameters. The reasons for this are as follows: first of all, the higher the performance parameters of the test sample under normal circumstances are, the easier it is for the performance parameters of the test sample to show a linear relationship over time within the subsequent test time, and the test result may be used in a better way to predict the change in the performance parameters; secondly, the receiving party may have certain requirement for initial performance parameters in the course of product delivery, and therefore only the test result, which is obtained by testing the test sample with higher initial performance parameters than this requirement, is valid.

The requirement from the receiving party may come from internal discussions, or industry standards. Since the requirements made by different customers differ from each other, the test procedure is usually performed in accordance with the standards of JEDEC in this industry.

S4: inputting an AC signal to an input end of the wordline driver, to control the wordline to be repeatedly on and off through the wordline driver.

The step of controlling the wordline 12 to be repeatedly turned on and off through the wordline driver 11 specifically includes: controlling, at a previous moment, the PMOS transistor 113 to be turned on and the NMOS transistor 114 to be turned off, so that the wordline 12 is on; and controlling, at a later moment, the PMOS transistor 113 to be turned off and the NMOS transistor 114 to be turned on, so that the wordline 12 is off. The fact that the wordline 12 is controlled to be repeatedly on and off through the wordline driver 11 means a reliability test for the wordline driver 11. The input end 111 of the wordline driver 11 may input AC signals continuously, and may also input DC signals with different voltages in an alternate manner. In this embodiment, the operating temperature of the wordline driver 11 during an aging test is lower than the room temperature. Under conditions lower than the room temperature (hereinafter referred to as low temperature), atomic vibration of silicon atoms in channel regions of an MOS transistor becomes weaker, and collision of carriers with the silicon atoms is reduced while the carriers operate in an electric field, so it is easier to obtain a kinetic energy exceeding the barrier height of silicon-silicon dioxide to enter a gate oxide layer, which in turn causes interfacial damages and oxide traps of silicon-silicon dioxide, i.e., the hot carrier effect becomes more notable under low temperature conditions. That is, performing the test under conditions lower than the room temperature helps strengthen the influence of the hot carrier effect upon the PMOS transistor 113 and the NMOS transistor 114, thereby obtaining the degraded performance of the wordline driver 11 under high-strength hot carrier effect conditions.

As such, it can be ensured that the degraded performance of the wordline driver 11 under room temperature conditions or under higher temperature conditions meets the preset requirement by enabling the degraded performance of the wordline driver 11 under the high-strength hot carrier effect to meet the preset requirement. In addition, the test is performed under low temperature conditions and the test results under low temperature conditions are then equivalently converted to test results under room temperature or under conditions of other temperatures, which is conducive to accelerating the testing and improving the testing efficiency.

Likewise, in this embodiment, the voltage of the AC signal for testing is greater than the voltage of an operating signal of the wordline driver 11 during the reliability test for the wordline driver 11, so as to enhance the hot carrier effect, accelerate the testing and improve the testing efficiency. In this embodiment, the AC signal has an input duration of greater than 200 h, which is to say the duration of the reliability test is greater than 200 h. The duration of the reliability test is dictated by the standards of JEDEC.

As the test progresses, the hot carrier effect will cause damages to the gate medium layers of the PMOS transistor 113 and the NMOS transistor 114, which in turn leads to degradation of the performance parameters of the PMOS transistor 113 and the NMOS transistor 114. The PMOS transistor 113 and the NMOS transistor 114 are components of the wordline driver 11, and performance degradation of the wordline driver 11 includes performance degradation of the PMOS transistor 113 and performance degradation of the NMOS transistor 114.

In this embodiment, as shown in FIG. 4, while the voltage of the wordline 12 rises from a low voltage to a high voltage, the PMOS transistor 113 is gradually turned on, and the NMOS transistor 114 is turned off. The output voltage change rate of the output end 112 is only related to the turn-on rate of the PMOS transistor 113. Since the turn-on rate of the PMOS transistor 113 is related to the damages to the gate medium layer of the PMOS transistor 113, greater damages lead to more severe performance degradation, lower turn-on rate of the PMOS transistor 113, longer time for the voltage of the wordline 12 to rise from a low voltage to a high voltage, and longer addressing delay time of the wordline 12. Therefore, the addressing delay time may be used to characterize the current performance parameters of the PMOS transistor 113, and the addressing delay time at different moments may be used to characterize the hot carrier effect degraded performance of the PMOS transistor 113.

Correspondingly, while the voltage of the wordline 12 drops from a high voltage to a low voltage, the PMOS transistor 113 is gradually turned off, and the NMOS transistor 114 is turned on. The output voltage change rate of the output end 112 is only related to the turn-on rate of the NMOS transistor 114. Since the turn-on rate of the NMOS transistor 114 is related to the damages caused by the hot carrier effect to the gate medium layer of the NMOS transistor 114, greater damages lead to more severe performance degradation, lower turn-on rate of the NMOS transistor 114, longer time for the voltage of the wordline 12 to drop from a high voltage to a low voltage, and longer pre-charging time of the wordline 12. Therefore, the pre-charging time may be used to characterize the current performance parameters of the NMOS transistor 114, and the pre-charging time at different moments may be used to characterize the hot carrier effect degraded performance of the NMOS transistor 114.

In this embodiment, the wordline driver 11 are evaluated through a plurality of wordlines located at different positions in the same physical storage 13, one wordline 12 is controlled to be repeatedly on and off through the wordline driver 11 in each reliability test, and different wordlines 12 are controlled to be repeatedly on and off in different reliability tests. As a consequence, the hot carrier effect degraded performance of the wordline driver 11 to which the plurality of wordlines 12 are corresponding can be tested.

S5: performing the electrical test on the wordline.

The second electrical test is designed to judge whether the basic functions of the test sample are intact. In particular, the PMOS transistor 113 and the NMOS transistor 114 in the wordline driver 11 can be normally turned on and off. When the basic functions of the test sample are defective, it can be directly determined that the hot carrier effect degraded performance of the wordline driver 11 does not meet the preset requirement.

S6: performing the characteristic test on the sample passing the electrical test, to obtain a second performance parameter, and evaluating the hot carrier effect degraded performance of the wordline driver according to the first performance parameter and the second performance parameter.

The second performance parameter of the wordline driver 11 is obtained from the second characteristic test. The second performance parameter includes second addressing delay time and second pre-charging time, so that the hot carrier effect degraded performance of the PMOS transistor 113 is evaluated according to the first addressing delay time and the second addressing delay time, and the hot carrier effect degraded performance of the of the NMOS transistor 114 is evaluated according to the first pre-charging time and the second pre-charging time.

It shall be noted that one or more characteristic tests can be performed within 200 hours of the reliability test, in order to measure how the addressing delay time and the pre-charging time of the wordline 12 change. With reference to FIG. 5, the addressing delay time 21 and the pre-charging time 22 of the wordline 12 gradually increase during the reliability test. In accordance with the standards of JEDEC, after the reliability test, the hot carrier effect degraded performance of the wordline driver 11 is evaluated as unacceptable if the addressing delay time 21 and the pre-charging time 22 are greater than range values as stipulated in the standards of JEDEC, and if the addressing delay time 21 and the pre-charging time 22 are within the range values as stipulated in the standards of JEDEC, then the addressing delay time 21 can be used to evaluate the hot carrier effect degraded performance of the PMOS transistor 113 and the pre-charging time 22 can be used to evaluate the hot carrier effect degraded performance of the NMOS transistor 114.

In this embodiment, the AC signal is employed to perform the test for hot carrier effect degraded performance. Since the actual operating signal is the AC signal, there is no need to conduct equivalent conversion of the test result when the AC signal is applied to testing, i.e., there is no need to measure the duty cycle of the AC signal, which is the parameter for equivalent conversion, and this helps to avoid errors in measuring the duty cycle parameter and further to accurately evaluate the hot carrier effect degraded performance of the wordline driver. By measuring the specific performance parameters of the wordline driver during its actual operation, the influence of the HCI effect upon the wordline driver can be effectively evaluated, while at the same time evaluating the reliability of the PMOS and NMOS transistors.

The ordinary skills in the art can understand that the implementations described above are particular embodiments for implementing the present application. In practical uses, various changes in forms and details may be made to the implementations without departing from the spirit and scope of the present application. Any skills in the art may make their own changes and modifications without departing from the spirit and scope of the present application. Therefore, the protection scope of the present application shall be subject to the protection scope of the claims.

What is claimed is:

1. An evaluation method for hot carrier effect degraded performance, comprising:
providing at least one wordline and at least one wordline driver;
performing an electrical test on the wordline;
performing a characteristic test on a sample passing the electrical test, to obtain a first performance parameter;
inputting an alternating current (AC) signal to an input end of the wordline driver, to control the wordline to be repeatedly on and off through the wordline driver;
performing the electrical test on the wordline; and
performing the characteristic test on the sample passing the electrical test, to obtain a second performance parameter, and evaluating the hot carrier effect degraded performance of the wordline driver according to the first performance parameter and the second performance parameter.

2. The evaluation method for hot carrier effect degraded performance according to claim 1, wherein the first performance parameter and the second performance parameter of the wordline comprise addressing delay time and pre-charging time in memory timing; the first performance parameter comprises first addressing delay time and first pre-charging time, and the second performance parameter comprises second addressing delay time and second pre-charging time.

3. The evaluation method for hot carrier effect degraded performance according to claim 2, wherein the AC signal has an input duration of greater than 200 h.

4. The evaluation method for hot carrier effect degraded performance according to claim 2, wherein the addressing delay time and the pre-charging time are dictated by standards of Joint Electron Device Engineering Council (JEDEC).

5. The evaluation method for hot carrier effect degraded performance according to claim 1, wherein the wordline and the wordline driver are located in an array region.

6. The evaluation method for hot carrier effect degraded performance according to claim 1, wherein the wordline comprises a plurality of wordlines located at different positions in a same physical storage.

7. The evaluation method for hot carrier effect degraded performance according to claim 1, wherein the wordline is located at an edge of physical storage.

8. The evaluation method for hot carrier effect degraded performance according to claim 7, wherein in a direction of arrangement of the wordlines in the same physical storage, the wordline comprises at least one of a second wordline or a penultimate wordline.

9. The evaluation method for hot carrier effect degraded performance according to claim 7, wherein the step of inputting an AC signal to an input end of the wordline driver to control the wordline to be repeatedly on and off through the wordline driver comprises: controlling one wordline to be repeatedly on and off through the wordline driver in each test, and controlling different wordlines to be repeatedly on and off in different tests.

10. The evaluation method for hot carrier effect degraded performance according to claim 1, wherein the wordline driver is a functional circuit configured for practical read and write operations.

11. The evaluation method for hot carrier effect degraded performance according to claim 1, wherein the wordline driver comprises a PMOS transistor and an NMOS transistor, a gate of the PMOS transistor and a gate of the NMOS transistor are connected to function as the input end of the wordline driver, a drain of the PMOS transistor and a drain of the NMOS transistor are connected to function as an output end of the wordline driver, the output end of the wordline driver is connected with the wordline; a source of the PMOS transistor is connected with a working power supply, and a source of the NMOS transistor is grounded.

12. The evaluation method for hot carrier effect degraded performance according to claim 11, wherein the step of controlling the wordline to be repeatedly on and off through the wordline driver comprises: controlling, at a previous moment, the PMOS transistor to be turned on and the NMOS transistor to be turned off, so that the wordline is on; and controlling, at a later moment, the PMOS transistor to be turned off and the NMOS transistor to be turned on, so that the wordline is off.

13. The evaluation method for hot carrier effect degraded performance according to claim 12, wherein the first performance parameter and the second performance parameter of the wordline comprise addressing delay time and pre-charging time; the step of acquiring the performance parameters specifically comprises: controlling the PMOS transistor to be turned on and the NMOS transistor to be turned off, to acquire the addressing delay time; and controlling the PMOS transistor to be turned off and the NMOS transistor to be turned off, to acquire the pre-charging time.

14. The evaluation method for hot carrier effect degraded performance according to claim 13, wherein the hot carrier effect degraded performance of the PMOS transistor is evaluated through first addressing delay time and second addressing delay time; and the hot carrier effect degraded performance of the NMOS transistor is evaluated through first pre-charging time and second pre-charging time.

15. The evaluation method for hot carrier effect degraded performance according to claim 1, wherein a voltage of the AC signal is greater than a voltage of an operating signal of the wordline driver, and the AC signal is input to the input end of the wordline driver under a testing environment lower than room temperature.

16. The evaluation method for hot carrier effect degraded performance according to claim 5, wherein the wordline comprises a plurality of wordlines located at different positions in a same physical storage.

17. The evaluation method for hot carrier effect degraded performance according to claim 5, wherein the wordline is located at an edge of physical storage.

18. The evaluation method for hot carrier effect degraded performance according to claim 10, wherein the wordline driver comprises a PMOS transistor and an NMOS transistor, a gate of the PMOS transistor and a gate of the NMOS transistor are connected to function as the input end of the wordline driver, a drain of the PMOS transistor and a drain of the NMOS transistor are connected to function as an output end of the wordline driver, the output end of the wordline driver is connected with the wordline; a source of the PMOS transistor is connected with a working power supply, and a source of the NMOS transistor is grounded.
